(19) United States
(12) Patent Application Publication
(10) Pub. No.: US 2023/0040854 A1
(43) Pub. Date: Feb. 9, 2023

(54) Method and device for treating a surface of an accelerating cavity by ion implantation

(71) Applicant: Matthieu Cavellier, Saint Gildas de Rhuys (FR)

(72) Inventor: Matthieu Cavellier, Saint Gildas de Rhuys (FR)

(21) Appl. No.: 17/909,068

(22) PCT Filed: Feb. 9, 2021
(86) PCT No.: PCT/EP2021/053014

§ 371 Date: Sep. 2, 2022

(30) Foreign Application Priority Data
Mar. 5, 2020 (FR) FR2002213

(51) Int. Cl. C23C 14/48; H01J 37/317; H01J 37/147; H05H 7/18

(52) U.S. Cl. CPC C23C 14/48; H01J 37/3171; H01J 37/1474; H05H 7/18

(57) ABSTRACT

A technique for treating the surface of one or more accelerator cavities of an accelerator module. This technique relies on the use of a particle beam to at least partially scan the inner surface of the one or more accelerator cavities. Such a technique offers a treatment solution that is more suitable for accelerator cavities, with better control of the implantation parameters.

### FIELD OF INVENTION

The invention is in the field of surface treatment. More particularly, the invention relates to a technique for treating the inner surface of cavity, such as those used for example in the particle accelerator, commonly called accelerating cavities or resonant cavities.

### PRIOR ART

The following of this document is more particularly concerned with the problem existing in the field of superconductor particle accelerators, with which the inventors of the present patent application have been confronted. The invention is of course not limited to this particular field of application, but is of interest to any surface treatment technique that has to deal with a close or similar problem.

Particle accelerators are devices intended for the acceleration, at high energy, of elementary particles. Among the various existing devices, some are equipped with one or more accelerator modules in the form of a succession of (RF) radio frequency accelerating cavities in each of which the particles are accelerated by means of an electromagnetic field applied to that. The shape and dimensions of the accelerating cavities vary from one accelerator to another, and depend on various factors. These RF accelerating cavities can be made of different metallic materials or alloys, the most commonly used being copper and niobium (chemical symbol Nb). Niobium is a superconducting material that provides excellent performance at very low temperatures (typically below 2° K). In such cavities, superconductivity makes it possible to reduce the surface resistance of the inner walls thereof. The phenomenon is therefore a phenomenon localized at the level of the first nanometric layers of niobium.

In order to improve the resonance performance of accelerating cavities, it has been demonstrated by the way that a surface treatment by nitrogen doping of the niobium walls was possible, in particular to increase the quality factor of these cavities. Such treatment nevertheless remains a delicate operation to implement, in particular due to the shape and dimensions of the accelerating cavities, and the difficult access to certain internal regions of these.

A known treatment method is based on a technique of doping by nitrogen infusion of niobium cavities. This process consists of a high temperature heat treatment of the niobium cavities (typically between 600 and 1000° C.) in a treatment chamber saturated with nitrogen gas. Such a method makes it possible to modify the physico-chemical properties of the surface and internal structure of the cavity so that the quality factor is improved. However, this is a time-consuming and energy-intensive process. In addition, the nitrogen concentration as well as the depth of nitrogen infused into the walls of the cavities remain difficult to control with this type of process. Finally, it requires the use of treatment chambers of relatively large sizes, depending on the dimensions and the particular geometry of the accelerating cavities. Finally, with this process, it is necessary to carry out an electro-chemical polishing step inside the cavities to remove the layer of niobium nitride formed on the surface over several microns in thickness (of the order of 5 to 10 μm). Indeed, the high temperature treatment leads to the formation of a layer of niobium nitride which has the effect of degrading the superconducting properties and greatly increasing the surface resistance of the cavities. This electro-chemical polishing treatment also makes it possible to find an acceptable roughness to obtain the desired properties.

It would therefore appear to be of particular interest to have a surface treatment technique that is technically more suitable for accelerating cavities, offering in particular better control of the doping parameters with a view to greater treatment efficiency.

### SUMMARY OF THE INVENTION

In a particular embodiment of the invention, there is proposed a method for treating the surface of at least one accelerating cavity of an accelerator module, the method comprising a step of using a particle beam to treat, by implantation of particles, an internal surface of said at least one cavity.

By “internal surface” it means that all or part of the internal surface of said at least one cavity. In other words, the use of the particle beam according to the invention is implemented to treat at least partially the internal surface of said at least cavity.

Thus, the present invention proposes an alternative to the techniques of the prior art, consisting in subjecting the internal surface of one or more accelerating cavities to a particle beam, in order to carry out a surface treatment by implantation of particles. This new approach offers the possibility of carrying out a surface treatment of accelerating cavities at low temperatures (i.e. of the order of the ambient temperature), such a treatment being able to be carried out selectively or not. This new approach also allows, unlike the method of the aforementioned prior art (infusion doping), better control of the implantation parameters, in particular better control of the depth and concentration of implantation.

According to a particular aspect of the invention, the step of use includes a step of scanning the internal surface by displacement of the particle beam with respect to said internal surface or vice versa. Thus, it is possible to carry out a surface treatment which is effective and qualitative. The implementation of a scanning of a particle beam notably allows easier access to certain internal parts of the cavity which are difficult to access. Thus, unlike the prior art, the invention offers a method which adapts more easily to the dimensions and shapes of the accelerating cavities to be treated. Furthermore, the use of a particle beam makes it possible to use a lower quantity of particles than in the case of doping by infusion according to the prior art. In addition, the advantage of a low temperature treatment makes it possible to avoid, or at least reduce, the formation on the surface of chemical compounds harmful to the properties of the cavities. This makes it possible to dispense with an electro-chemical polishing step, as is the case with the prior art method. In fact, the invention offers a treatment solution that is simple and inexpensive to implement.

According to a particular characteristic, the scanning step is preceded by the following steps:

introduction into said at least one cavity, via an orifice of the accelerator module, of an electric and/or magnetic scanning head of the internal surface;

vacuum generation of the particle beam in the direction of the scanning head introduced into said at least one cavity;

said scanning step being implemented by activating the scanning head.

Thus, the invention provides for the possibility of performing electric, magnetic or electromagnetic scanning of the internal surface, by simple activation of a scanning head previously introduced into the cavity. The scan is performed around a first scan axis.

According to a complementary aspect of the invention, the scanning step comprises a step of driving said at least one cavity in rotation with respect to the scanning head or vice versa. The rotational drive is performed around a second scanning axis. Thus, the invention provides the possibility of further performing mechanical scanning of the internal surface, by simple rotation of the cavity relative to the scanning head or vice versa.

Alternatively or additionally, the scanning step comprises a step of driving the scanning head in translation with respect to said at least one cavity or vice versa. The drive in translation is carried out along the aforementioned second scanning axis. Thus, the invention provides another way of mechanically sweeping the internal surface of a cavity. The rotational and translational drive steps can be performed successively or simultaneously depending on the desired scanning configuration.

According to a particular aspect of the invention, the particles of the beam are particles selected from the species belonging to the group comprising: an atomic species, a molecular species, an ionic species, a molecular and ionic species, a species based on at least one elementary particle. The method according to the invention is therefore compatible with different types of particles to be implanted, the choice depending on the material of the internal walls of the treated cavity as well as the nature of the desired surface treatment.

According to a particular aspect of the invention, the particles of the beam are ions selected from the elements belonging to the group comprising: nitrogen (N), helium (He), titanium (Ti), argon (Ar), oxygen (O), iron (Fe), aluminum (Al), neon (Ne), krypton (Kr), xenon (Xe), boron (B), carbon (C), fluorine (F), silicon (Si), phosphorus (P), sulfur (S). The process according to the invention is therefore compatible with ions of different natures. This list of items is not necessarily exhaustive. The choice depends on the material of the cavity treated as well as the nature of the desired surface treatment.

According to a particularly advantageous characteristic, the internal surface of said at least one cavity being made of niobium (Nb), the particle beam used is a beam of nitrogen ions with a single charge or with multiple charges. The use of such a beam makes it possible to improve the resonance quality factor of the niobium cavities thus treated.

The invention also relates to the products obtained directly from the process and their subsequent use, in particular in a particle accelerator. Thus, according to another particular embodiment, there is proposed an accelerating cavity of an accelerator module obtained by the aforementioned processing method in any one of its various embodiments. It should be noted in this respect that such a treatment process generally takes place in a more global process of manufacturing accelerating cavity for a particle accelerator. Such an accelerating cavity is obtained by the surface treatment implemented by the aforementioned method, characterized by a step of scanning an internal surface of the cavity by displacement of the particle beam relative to the internal surface or vice versa. After treatment, the accelerating cavity has a quality factor between 1×10¹¹ and 1×10¹⁴.

In another embodiment of the invention, a computer program product is provided which includes program code instructions for implementing the above method (in any of its various embodiments), when said program is run on a computer.

In another embodiment of the invention, there is provided a computer-readable, non-transitory storage medium storing a computer program comprising a set of computer-executable instructions for carrying out the above method (in any of its various embodiments).

In another embodiment of the invention, there is proposed a surface treatment device for at least one accelerating cavity of an accelerator module, comprising means for scanning an internal surface of said at least one cavity by means of a particle beam.

Thus, the present invention proposes an alternative to the surface treatment devices of the prior art, which is more efficient and simpler to implement. The general principle of the invention, in this embodiment, consists in subjecting the internal surface of one or more accelerating cavities to a particle beam scan in order to carry out therein a surface treatment by implantation of particles. This new approach makes it possible to perform a low temperature treatment, which can be selective (for example by scanning a portion of the internal surface of the cavity) or non-selective (for example by scanning the entire surface internal). Finally, compared to the aforementioned prior art, the use of a particle beam offers better control of the implantation parameters, in particular the depth and the concentration of implanted particles.

In a complementary manner, the device further comprises:

means for introducing into said at least one cavity an electric and/or magnetic scanning head of the internal surface, said means for introducing and the scanning head being configured to be insertable into said at least one cavity;

means for generating the particle beam under vacuum in the direction of the scanning head; said scanning means comprising the scanning head.

More particularly, the scanning head comprises a beam deflector capable of deflecting the generated beam towards the internal surface and a beam exit aperture arranged with respect to the beam deflector so as to let the deflected beam pass in the direction of the internal surface. In this way, by applying a simple electric and/or magnetic force, the particle beam is deflected from its trajectory within the cavity itself for surface treatment purposes. The invention in fact provides for the possibility of carrying out a purely electrical, magnetic or electromagnetic scan around a first scanning axis, to treat the internal surface of the cavity.

In a complementary manner, the scanning means comprise means for driving said at least one cavity in rotation with respect to the scanning head or vice versa. Thus, in a clever way, a purely mechanical or hybrid scanning of the electrical-mechanical or magnetic-mechanical type can be carried out to treat the internal surface of the cavity.

Complementarily or alternatively, said scanning means comprise means for driving the scanning head in translation with respect to said at least one cavity or vice versa. Thus, the invention also provides for the possibility of performing scanning alone or in combination with the aforementioned rotational drive means.

According to a particular configuration, the accelerator module comprising a plurality of successive accelerating cavities, the translational drive means are configured to successively introduce the scanning head in order to scan the internal surface of each of the cavities of said plurality. It is thus possible to treat the internal surface of several cavities successively over time with a single scanning head.

According to a variant embodiment, the accelerator module comprising a plurality of successive accelerating cavities, the introduction means comprise a plurality of distinct scanning heads arranged successively along said introduction means, each scanning head being configured so as to operate scanning the inner surface of a cavity different from said plurality. This variant is particularly interesting since it makes it possible to carry out a treatment of several cavities without having to carry out a translation of the scanning head during the multi-cavity treatment. Such a configuration is therefore simpler to implement and makes it possible to reduce the processing time. Moreover, by comparison with the particular configuration mentioned above, for an accelerator module of the same length, it makes it possible to have recourse to means of introduction of length reduced by half. Note the dual function of the drive means in translation according to the invention: the positioning of the scanning head in at least one accelerating cavity and, if necessary, the participation in the scanning of the internal surface of the latter according to the first scanning axis.

According to a particular characteristic, the device is configured to form with the accelerator module an enclosure capable of being placed under vacuum. In this way, the device and the accelerator module form a system comprising a processing enclosure that can be placed under a controlled atmosphere. Thus, unlike the aforementioned prior art where the accelerator module is placed in a dedicated processing enclosure, the device according to the invention takes advantage of the accelerator module (regardless of the number of cavities) to form a processing enclosure, and therefore offer a device with reduced dimensions. In this case, the treatment enclosure is formed by: said at least one accelerating cavity, the connection and vacuum guide connecting the means for generating the particle beam under vacuum to the first orifice of said at least one cavity and an absorbent closure member coupled to the second port of said at least one cavity. Putting the containment under vacuum facilitates the use of the particle beam generated by the generation means.

More generally, the processing device according to the invention comprises means for implementing the steps that it performs in the processing method as described above, in any one of its various embodiments.

### DRAWINGS

Further characteristics and advantages of the invention will become apparent from the following description, given as an indicative and non-limiting example, and from the appended drawings, among which:

FIG. 1 illustrates a simplified synoptic of a treatment device in accordance with a particular embodiment of the invention;

FIG. 2 is a generic chart of a particular embodiment of the method according to the invention;

FIG. 3 illustrates the operation of the device illustrate on FIG. 1 to multi-cavity treatment;

FIG. 4 illustrates a variant of implementation of the device illustrated on FIG. 3 in accordance with the invention;

FIG. 5a and FIG. 5b illustrate schematic views of a first example of scanning head according to the invention;

FIG. 6a and FIG. 6b illustrate schematic views of a second example of scanning head according to the invention;

FIG. 7 presents a simplified schema of the structure of a control unit implementing the method according to a particular embodiment of the invention.

### DETAILED DESCRIPTION OF INVENTION

In the figures of this document, identical elements are designated by the same reference numeral.

The general principle of the invention is based on the use of a particle beam to treat the internal surface of one or more accelerating cavities of an accelerator module. Such an approach makes it possible to carry out an effective surface treatment, particularly well-suited to this type of cavity.

In the remainder of this document, particular attention is paid to describing the invention in the case of a linear superconducting accelerating structure. Of course, this is a particular application example, which can easily be adapted to many other applications, without departing from the scope of the invention.

[symbol] Single-Cavity Treatment

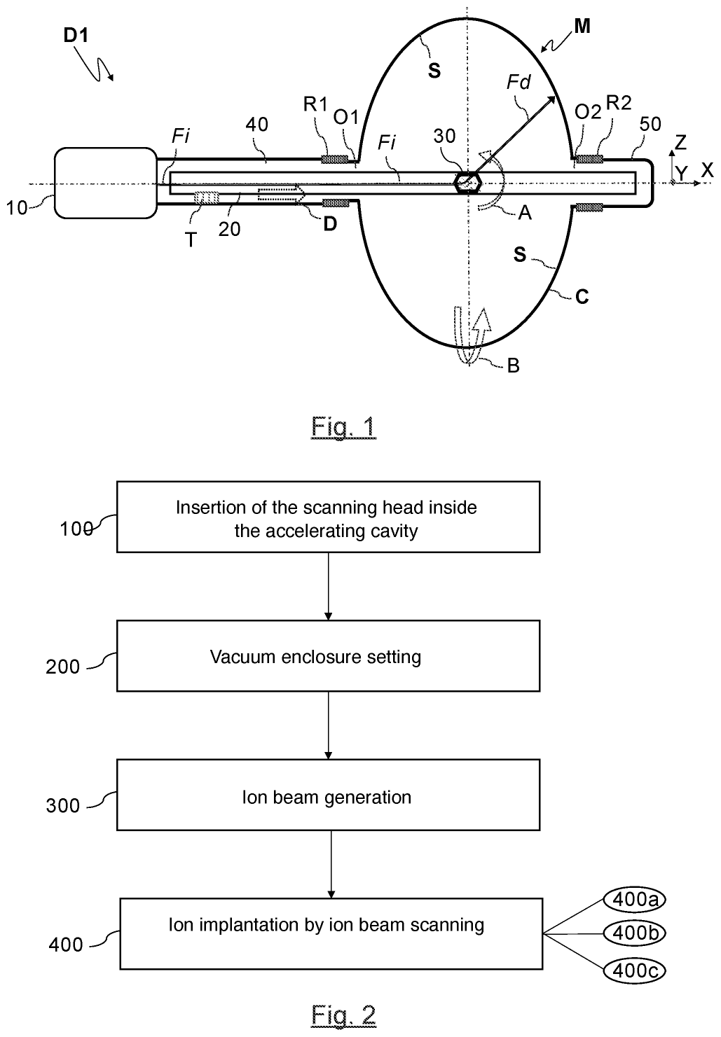

FIG. 1 schematically presents the principle of operation of a treatment device D1, according to a particular embodiment of the invention.

In this particular embodiment, the device D1 is configured to treat the internal surface S of an accelerating cavity C by ion implantation. This surface treatment aims to increase the resonance performance of the accelerating cavity.

The accelerator module M represented in this figure by way of example comprises only one accelerating cavity. The surface S of the accelerating cavity C is made of niobium (symbol Nb), a superconducting material frequently used in the manufacture of accelerator modules. The particle beam used here is a nitrogen-based ion beam. The device D1 and the accelerator module M form a treatment system according to the invention, represented here in a reference system X, Y, Z.

Cavity C has a symmetry of revolution around a longitudinal axis X. This axis is materialized by the dotted line X in the figure. Orthogonally to this longitudinal axis X, the cavity C extends radially in YZ plane, but progressively along the longitudinal axis X, defining a substantially toric general shape. Cavity C comprises an inlet orifice O1 and an outlet orifice O2, of circular section, both centered on the longitudinal axis X.

In order to make the surface treatment more efficient and less costly, in particular in terms of energy, the device according to the invention has scanning means configured to carry out a controlled scanning of the internal surface S of the cavity C by means of a beam of ions. Scanning is carried out by displacement of the ion beam with respect to the internal surface S or conversely, by displacement of the internal surface S with respect to the ion beam. The scanning means presented below are of different types. They can be operated singly or in combination, sequentially or simultaneously, depending on the intended scan configuration. The principle of use of the ion beam is described in detail later, in relation to FIG. 2.

In this particular embodiment, the device D1 comprises:

means 10 for generating a beam of ions, for example an electron cyclotron resonance source (or ECR source) configured to generate a beam of mono-charged nitrogen ions (of symbol N+);

a magnetic scanning head 30, capable of scanning the internal surface S by deflecting the ion beam towards the internal surface S by means of a magnetic force applied to this beam;

means 20 for introducing the scanning head 30 into the cavity C;

a connection and vacuum guide 40;

an absorbent closure member 50 disposed at the cavity outlet;

a control unit 80 configured to control the means 10, 20, 30 and 40 mentioned above.

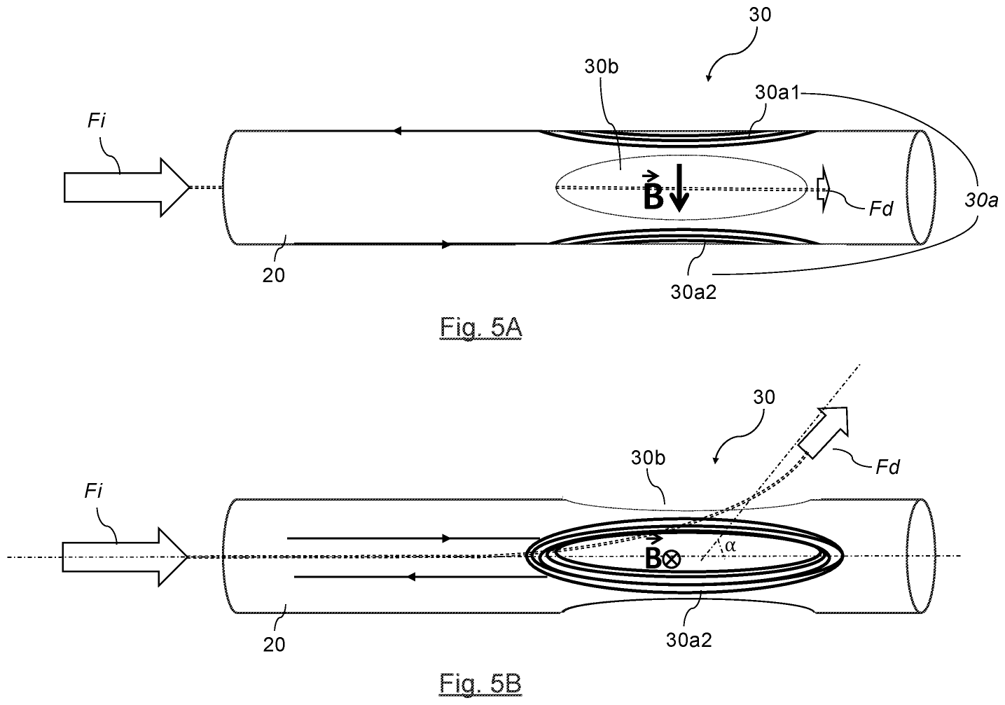

In the example shown here, the scanning means are ensured magnetically by means of the scanning head 30 included in the introduction means 20. Such a scanning head is composed, for example, of an exit opening of beam and a magnetic dipole arranged in the vicinity of said opening, as illustrated in FIGS. 5A and 5B.

The means of introduction 20 present here in the form of an elongated rod, centered on and extending along the longitudinal axis X. The rod 20 is designed so as to be sufficiently rigid to allow the carrying of the head of scanning 30 in the centre of the cavity C without undergoing mechanical deformation. The rod 20 is, moreover, dimensioned so as to allow its insertion and that of the scanning head 30 within the cavity C, through the orifices O1-O2. According to a particular aspect, the rod 20 must be shaped so as not to interfere with the incident ion beam Fi emitted by the source 10. For example, a rod of tubular shape, centered on and extending along the longitudinal axis X, is well suited to pass the ion beam through its centre along the longitudinal axis X. Further details on the implementation of the magnetic scan head 30 are given later in connection with FIGS. 5a and 5b.

The connection guide 40 is a tubular-shaped element, centered on and extending along the longitudinal axis X. It is connected in a sealed manner, on the one hand, to the source 10, and on the other hand to the inlet orifice O1 of the cavity C by means of an annular connection flange R1. The guide 40 is also provided with a support member T mounted in a fixed manner on the internal wall of the guide and arranged to carry the insertion rod 20 so that it is arranged in the longitudinal axis X. in a complementary manner, the support member T with which the guide 40 is provided can play the role of translator of the introduction rod 20 along the longitudinal axis X. Finally, a vacuum pump (not shown in the figure) is connected to the guide 40 by a sealed member (also not shown), in order to place the system under a controlled atmosphere.

The absorbent closure member 50 is in the form of a tube closed at one of its ends by an absorbent bottom, the other end being adapted to be connected, in a sealed manner, to the O2 outlet orifice. by means of an annular connection flange R2. The absorbent bottom comprises at least one layer of a material chosen for its properties of absorption of ionizing radiation (in other words, a material chosen for its stopping power to nitrogen ions in the present case), with a view to stopping for residual or unused ions during treatment). Thus, the member 50 performs the ion absorption function, but also the function of sealing the O2 outlet orifice.

According to a particularly advantageous configuration, the elements referenced 10, 40, O1, C, O2 and 50 are modular elements configured so as to form a sealed treatment enclosure, capable of being placed under vacuum. Indeed, in order to improve the performance of ion implantation, it is preferable to have a treatment chamber under controlled vacuum. This vacuum makes it possible to prevent the interception of the ion beam with residual gases and to avoid contamination, by these same gases, of the surface to be treated during the implantation process. The ion beam thus generated is more stable, thereby increasing the implantation precision. The enclosure is evacuated conventionally by means of the vacuum pump connected to the guide 40. Thus, unlike the prior art, it is no longer necessary to provide a full-fledged treatment enclosure, sized to accommodate the accelerator module, since the device according to the invention makes it possible to take advantage of the accelerator module M itself to form an enclosure in a controlled atmosphere. Thus, thanks to the invention, it is possible to have a treatment device with reduced size.

We have seen above that, in the example represented in FIG. 1, the scanning means are ensured by the magnetic scanning head 30 (hereinafter called “first scanning means”).

In a complementary manner, the scanning means according to the invention are also ensured by means for driving in rotation, around the longitudinal axis X, the cavity C with respect to the magnetic scanning head 30. These means of drive are mechanical in nature and are referred to below as “second scanning means”. They are represented here by the rotating annular flanges R1 and R2, arranged at the outlet of the inlet and outlet orifices O1 and O2, respectively. They are designed, more particularly, to allow the rotation of the cavity C with respect to the connection guide 40 on the one hand (provided by the rotary flange R1) and with respect to the closure member 50 on the other hand (provided by the rotary flange R2). The axis of rotation of the cavity C coincides with the longitudinal axis X. Each rotary flange R1-R2 is also provided with a part of the seal, of annular shape for example, making it possible to guarantee a vacuum-tight connection with each of the elements to which it is connected.

We now present, in relation to FIG. 2, the main steps of the method according to a particular embodiment of the invention. The method is implemented in part by a control unit, the principle of which is described in detail later in relation to FIG. 7. This control unit is configured so as to control the ion source 10, the first (30) and second (R1-R2) scanning means 30, as well as the vacuum pump. The control of these various elements by the control unit is carried out by means of control commands.

The device D1 is firstly mounted by assembling the following modular elements: the source 10 with the connection guide 40, the connection guide 40 with the inlet orifice O1 via the flange R1, the closing member absorbing 50 with outlet port via flange R2. The insertion rod 20 carrying the magnetic head 30 is introduced into the cavity C via the orifice O1 so that it is placed in the centre of the cavity C, as represented in FIG. 1. This insertion step, referenced 100 in FIG. 2, is performed manually at the time of assembly of the various modular elements. At least one modular element support structure can be used to make said modular element mobile and to facilitate assembly of the modular elements.

In a complementary or alternative manner, the magnetic head 30 can be introduced into the cavity C in an automated manner with the aid of a programmable automaton or with means for driving the rod 20 in motorized translation along the longitudinal X. This function is performed by the translator T in this example. In this case, the control unit must be configured to also control the translator T. Of course, it is also possible, as an alternative, to proceed with the introduction of the rod, and therefore of the head of scanning, via the outlet orifice, the above principle applying in an identical manner.

Next, in step 200, the treatment enclosure is placed under vacuum by activating the vacuum pump which is connected to the connection guide 40. When the pressure prevailing in the treatment enclosure is order of 10⁻⁵ to 10⁻⁸ mbar, it is considered that the vacuum has been reached in the enclosure and the next step is carried out.

Although it is preferable to put the treatment enclosure under vacuum to improve the ion implantation conditions according to the invention, one could very well consider a “degraded” embodiment in which the treatment enclosure is out of vacuum. (i.e. at atmospheric pressure).

In step 300, the source 10 is activated so that it produces under vacuum a beam of monocharged or multicharged nitrogen-based ions in the direction of the guide head 30, via the connection guide 40. Typically, the ion beam has a circular section and has a predetermined diameter, typically comprised between 0.5 and 200 mm. The diameter of the beam is chosen in particular according to the size of the cavity to be treated and the desired scanning speed. The ion beam is emitted with an acceleration voltage between 1 kV and 500 MV. The flow rate of the ion beam is adapted to form a layer of implanted ions of predefined thickness. As for the surface concentration of implanted ions, it mainly depends on the scanning speed of the beam at the surface of the cavity. The longer the beam exposure time, the greater the number of implanted ions per square centimeter. According to a particular implementation, the control unit can take account of the fluence to be obtained at the surface of the cavity (expressed in number of ions/cm²) so that the quality factor ultimately conferred on the treated cavity is at least above 3.10¹⁰. More particularly, a quality factor between 1×10¹¹ and 1×10¹⁴ can be obtained for niobium cavities treated according to the treatment with a nitrogen ion beam.

To obtain these parameters related to the ion beam, the control unit loads from a storage memory the scanning pattern which has been previously defined to carry out a scanning of the internal surface of the cavity C. This scanning pattern comprises typically a sequence of instructions making it possible to define the parameters of the beam to be emitted as well as the parameters of relative displacement of the ion beam with respect to the surface to be treated or vice versa This sequence of instructions, intended to be executed by the unit control, therefore includes a number of data relating to the scanning procedure to be carried out by it. Mention may be made, for example, of the acceleration voltage of the ion beam, the intensity of the ion beam, the diameter of the beam, the nature of the ions to be emitted, the scanning sequence with the scanning means to be activated, scan speed, scan step, etc., without this list being exhaustive.

Step 400 is based on the use of the ion beam generated by the source 10 to carry out a scanning of the internal surface of the cavity C with a view to improving its properties. The scan orchestrated by the control unit depends on the scan pattern it is performing.

According to a particular embodiment, the control unit carries out a magnetic-mechanical hybrid scanning of the surface S. The control unit then sends a sequence of commands making it possible to activate the first and second scanning means, depending instructions contained in the scan pattern.

Thus, when the magnetic head 30 is activated (first scanning means), it is the ion beam which is moved relative to the cavity C around a first scanning axis (axis of rotation coinciding with the axis Y of the cavity) to sweep the surface S around this axis. This step is materialized by arrow A in FIG. 1 and by box 400a in FIG. 2.

When the pair of rotary flanges R1-R2 is activated (second scanning means), it is the cavity C which is moved relative to the ion beam along a second scanning axis (axis of rotation coinciding with the X axis of the cavity) to scan the surface S around this axis. This step is materialized by arrow B in FIG. 1 and by box 400b in FIG. 2.

Note that the first and second scanning means can be activated sequentially or simultaneously during step 400 of the method.

Alternatively or additionally, the translator T ensuring the translation of the insertion rod 20 with respect to the module M, can also be activated to participate in the scanning of the internal surface of the cavity C, as a third scanning means. In this case, it is the ion beam which is moved with respect to the cavity C along a third scanning axis (translation axis coinciding with the longitudinal axis X). This optional step is materialized by the arrow C in FIG. 1 and by the box 400c in FIG. 2. These third scanning means can be implemented sequentially or simultaneously with the first and/or second scanning means. scanning during step 400 of the method.

The scanning scheme described here comprises a scanning cycle adapted to treat the entire internal surface of the cavity C by ion implantation (we then speak of exhaustive treatment). This is of course a particular embodiment, many other scanning schemes can be considered according to the needs defined by the user.

In order to guarantee a homogeneity of treatment, a scanning scheme with several scanning cycles can be envisaged for example.

In order to carry out a local treatment of the cavity, a scanning cycle in accordance with the above principle but targeted only on a portion or a plurality of distinct portions of the internal surface, can also be envisaged (we then speak of selective treatment).

Finally, the use of an ion beam according to the invention offers the possibility of an implantation of ions at depths and concentrations which can be constant at any point of the treated surface or variable according to the needs. Indeed, it has been demonstrated that these two implantation parameters depend on the implantation energy of the ion beam. However, the implantation energy itself depends on two factors in particular: the distance traveled by the ion beam from the source to the point of impact on the surface, on the one hand, and on the other hand, the angle of incidence of the ion beam relative to the surface at the point of impact of the beam on the surface. As these two factors may vary during the treatment, the aforementioned implantation parameters may be affected. To compensate for this defect, whether it is the module M or the beam which is moved, the relative speed of movement of these two elements during the treatment can be modulated in order to modify the quantity of ions implanted at the level of the surface S in taking into account at least one of the two aforementioned factors.

Thus, according to a particular implementation, the scan pattern defines a scan rate which is constant. Alternatively, the scanning scheme defines a scanning speed which is variable to take account of the geometry of the cavity to be treated. This has the effect of homogenizing the implantation of ions over the entire surface to be treated.

According to another alternative, the scanning scheme defines a scanning speed which is a function of a predefined concentration or implantation depth profile for a given cavity. This implementation is particularly advantageous in that it makes it possible to produce precise ion implantation profiles, which are difficult to obtain with the doping technique of the prior art.

At the end of step 400, the vacuum pump is stopped in order to put the enclosure back under atmospheric pressure. An accelerating cavity with an increased quality factor is thus obtained.

It should be noted that, depending on the applications envisaged and in particular the shape and dimensions of the accelerating cavities to be treated, the shape and dimensions of the constituent elements of the device according to the invention are not limited to the embodiment example discussed above. For example, elements such as the introduction rod, the connection guide, the annular flanges and the absorber can take different shapes, and have dimensions adapted to the accelerator module to be treated.

The ion beam is emitted here by an electron cyclotron resonance source. This type of source is commonly used to produce mono-charged or multi-charged ions, i.e. atoms of a given chemical species from which one or more electrons have been removed. This example is not limiting and other types of sources capable of generating a high-energy particle beam can be used within the scope of the invention, such as for example a discharge, ionization, thermo-ionization source or plasma, without being exhaustive. It is also preferable for the source to be equipped to receive a high vacuum, or even an ultra-high vacuum, to guarantee the formation of a beam of particles of the desired shape (except for the plasma source).

Note also the possibility of using, not an ion source dedicated to surface treatment as illustrated in the example above, but the original source of the particle accelerator for which the cavities are to be treated. Indeed, said original source being initially configured to produce particles at high energy along the longitudinal axis of the acceleration module, it may be advantageous to use this original source as means for generating a beam according to the invention to treat the internal surface of the cavities of this module.

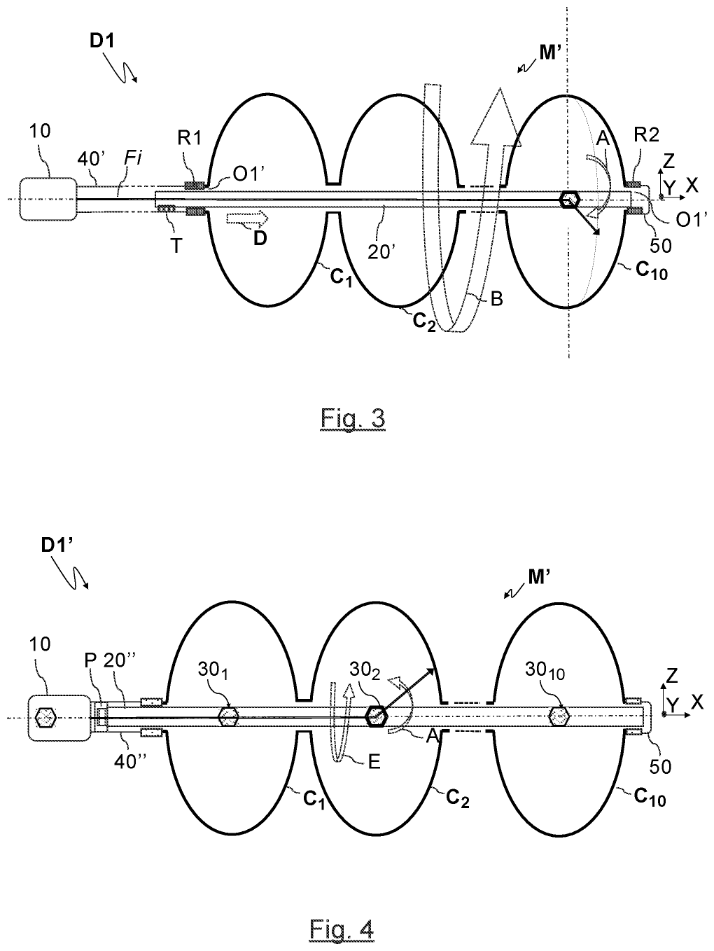

Finally, note that the accelerator module M illustrated here has only one accelerating cavity. The number of accelerating cavities represented here is voluntarily limited, initially, as a purely educational description. Of course, it is possible to carry out a surface treatment in accordance with the invention with a larger number of accelerating cavities, as illustrated below in relation to FIGS. 3 and 4.

[symbol] Multi-Cavity Treatment

The operating principle of a multi-cavity treatment device is described below, in relation to FIG. 3, according to a particular embodiment of the invention. Unlike FIG. 1, the accelerator module M′ consists of a set of ten successive accelerating cavities, referenced C₁-C₁₀. Each of these cavities is mainly composed of niobium, as for cavity C described above. The accelerator module M′ comprises an inlet orifice O1′ and an outlet orifice O2′ centered on the X axis. As for the treatment device, it comprises an introduction rod 20′ and a connection guide 40′ of dimensions adapted to the dimensions of the multi-cavity module M′. Indeed, these two elements must each have a suitable length so that the scanning head 30 can be introduced into each of the cavities of the module M′, from the cavity C₁ to the cavity C₁₀, by translation of the introduction rod 20′ along the longitudinal axis X.

In this particular configuration, the support member T which is fixed in the connection guide 40′ acts as a translator of the insertion rod 20 along the longitudinal axis X, thus making the insertion rod 20 movable in translation relative to the accelerator module M′. Thus, to scan the surface of each of the cavities C₁-C₁₀ of the module M′ using the ion beam according to the invention, the support member T is configured to successively introduce the head of scan 30 in each of the cavities C₁-C₁₀ of the module M′. The displacement by translation of the rod 20, and therefore of the scanning head 30, along the longitudinal axis X is materialized by the arrow D in the figure.

Let us take the example of the cavities C₁-C₁₀ treated successively according to the numerical order of these cavities 1 to 10. The control unit first proceeds to the execution of the aforementioned steps 100 to 400 (in accordance with the principle above applied for the cavity C) to treat the cavity C₁ of the module M′. Thus, after having introduced the scanning head 30 into the centre of the cavity C₁, the control unit scans the internal surface of this cavity C₁ by means of the beam of nitrogen ions emitted by the source 10. Then, once the scanning phase is finished for the cavity C₁, the control unit repeats the aforementioned steps 100 to 400 to process the cavity C₂ of the module M′. Thus, after having introduced the scanning head 30 into the centre of the cavity C₂, the control unit scans the internal surface of this cavity C₁ by means of the beam of nitrogen ions emitted by the source 10. And so on up to the cavity C₁₀ of the module M′. In FIG. 3, cavity C₁₀ is being processed.

Thanks to this particular configuration, it is possible to treat the internal surface of several cavities successively over time with a single scanning head. This configuration can be particularly advantageous for a limited number of cavities to be treated.

FIG. 4 illustrates a variant of the treatment device shown in FIG. 3, in accordance with the invention. Unlike FIG. 3, the device has a 20″ multi-scan head introducer rod. More precisely, this introduction rod 20″ comprises a set of ten scanning heads, referenced 301 to 3010, arranged successively along the scanning rod so that, when the rod 20″ is introduced into the module M′, each scanning head is placed at the centre of a different cavity of the module M′, for treatment of the internal surface of this cavity by means of an ion beam emitted by the source 10. Thus, the scanning heads 30₁ to 30₁₀ are dedicated respectively to the treatment of the cavities 30₁ to 30₁₀ of the module M′.

Furthermore, unlike FIG. 3, the second scanning means are no longer ensured by the pair of rotary flanges R1 and R2 ensuring the rotational drive of the module M′ around the longitudinal axis X with respect to the introduction rod, but by a stepper positioning motor P cooperating with the introduction rod 20″ so as to drive the introduction rod 20″ in rotation around the longitudinal axis X by relative to the modulus M′. This alternative is particularly advantageous to implement when the accelerator module constitutes a bulky part to be processed, thus avoiding the need for means of driving the module in rotation which are heavy, bulky and expensive.

FIGS. 5a and 5b illustrate the principle of operation of a magnetic scanning head according to the invention. These two figures represent enlarged and detailed views of a portion of the introducer rod 20.

Scanning head 30 includes a magnetic beam deflector 30a and a beam passage aperture 30b. The deflector presented here is a magnetic dipole made from a pair of windings of electric wires 30a1-30a2 (also commonly called “coils”) capable of receiving a predetermined electric current. This pair of coils 30a1-30a2 is arranged on the outer surface of the rod 20. The first winding of wires 30a1 constitutes the North pole of the magnetic dipole and the second winding of wires 30a2 constitutes the South pole of the magnetic dipole. The opening 30b is a through opening made in the introduction rod 200 perpendicular to the through axis of the pair of wire windings 30a1-30a2, so as to allow the ion beam deflected by the deflector 30b to pass, towards the internal surface of the cavity to be treated. The magnetic deflector 30a and the passage opening 30b are configured so that, depending on the electric current flowing in the magnetic deflector 30a, the incident beam Fi coming from the source 10 is deflected from its initial trajectory (deflected beam Fd), to be directed, via the opening 30b, towards the internal surface of the cavity according to a deflection angle α. This angle of deviation is defined by the axes of the incident beam Fi (axis coinciding with the longitudinal axis X) and of the deflected beam Fd, and depends on the magnetic force applied by the deflector 30a to the ion beam. The greater the intensity of the electric current passing through the deflector, the more the ion beam is deflected from its initial trajectory. The intensity of the electric current passing through the pair of windings is controlled by the control unit depending on the scanning pattern it performs.

Preference will be given to an area of occupation of each coil 30a1-30a2 greater than the area of occupation of the opening 30b, in order to guarantee effective and reliable control of the operation of the scanning head 30.

The magnetic deflector shown here is a purely illustrative example, and other types of magnetic deflector can be considered without departing from the scope of the invention. For example, a deflector based on one or more permanent magnet(s) or electromagnet(s), or even a more complex magnetic circuit capable of performing the aforementioned function may very well be suitable.

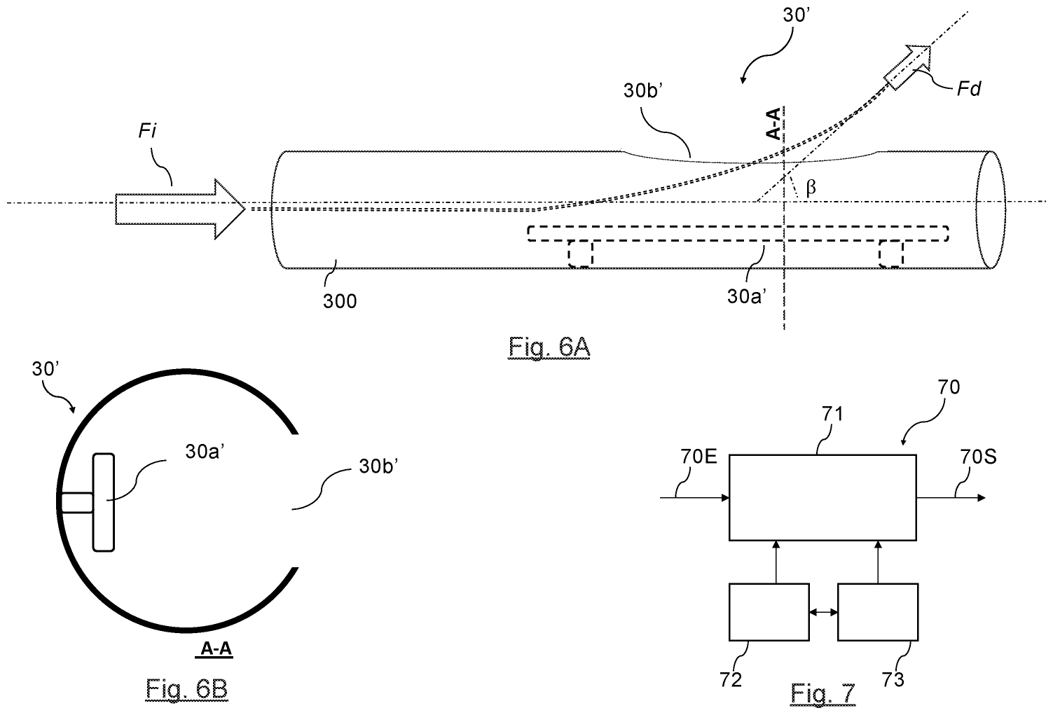

FIGS. 6a and 6b illustrate the principle of operation of an electric scanning head according to the invention. FIG. 6b is a sectional view along the axis A-A shown in FIG. 6a. The latter is an enlarged view of a portion of an introducer rod 300 according to the invention.

Unlike FIGS. 5a and 5b described above, the scan head 30′ shown here is electrical in nature. The scanning head 30′ includes an electrical beam deflector 30a′ and a beam passage aperture 30b′. The electric deflector 30a′ consists of an electrically conductive plate extending along the longitudinal axis X and capable of deflecting the ion beam when it is subjected to a predetermined electric voltage. This plate is fixedly mounted on the inner surface of the rod 30 via at least one electrically insulating support means. The opening 30b′ is a non-through opening made in the introduction rod 300 placed facing said plate, so as to let the ion beam deflected by the deflector 30b′ pass in the direction of the internal surface of the cavity to be treated. The electric plate 30a′ and the passage opening 30b′ are configured so that, depending on the electric voltage applied to the plate 30a′, the incident beam Fi coming from the source 10 is deflected from its initial trajectory (deflected beam Fd), to be directed, via the opening 30b′, towards the internal surface of the cavity according to a deflection angle β. Thus, unlike the previous configuration, it is the presence of an electric field on the incident beam which allows it to be deflected in the direction of the surface to be implanted. The principle of variability of the angle of deviation β is identical to that described above with the angle of deviation α (in relation to FIGS. 5a and 5b) but for an electric field. The level of electrical voltage applied to the conductive plate is controlled by the control unit depending on the scan pattern it is performing.

As before, preference will be given to a surface occupied by the electric plate greater than the surface occupied by the opening, in order to guarantee effective and reliable control of the operation of the scanning head 30′.

The electric deflector shown here is a purely illustrative example, and other types of deflector of an electrical nature can be envisaged without departing from the scope of the invention. For example, a simple pair of metal electrodes, an electrostatic element or even a more complex electrical circuit capable of carrying out the aforementioned function may very well be suitable.

Thus, in view of the above description, various elements having the function of deflecting or deflecting an ion beam (and more generally a charged particle beam) from its initial trajectory, are possible.

The description above has endeavored to describe the invention based on the use of a beam of monocharged nitrogen ions. However, this example is not limiting and the invention can be applied in all cases where a particle beam allowing implantation of particles on the cavity surface can be used.

More generally, the particles of the beam are particles which can be selected from the following species: an atomic species, a molecular species, an ionic species (as described above), a molecular and ionic species, a species based on at least one elementary particle, or a combination of at least two of these species. The invention is therefore compatible with different types of particles to be implanted. The choice of the particle(s) to be used depends on the material to be treated at the surface of the cavity and the nature of the desired treatment.

Finally, according to a particular aspect of the invention, the particles of the beam are ions selected from the following elements: nitrogen (with symbol N, as described above), helium (He), titanium (Ti), argon (Ar), oxygen (O), iron (Fe), aluminum (Al), neon (Ne), krypton (Kr), xenon (Xe), boron (B), carbon (C), fluorine (F), silicon (Si), phosphorus (P), sulfur (S) or a combination of at least two of these elements. The choice among these elements depends on the material to be treated at the surface of the cavity and on the nature of the surface treatment decided upon. In the event that the ion source of the device is a multiple ion source, an extractor filter (for example capable of extracting at least one specific type of ions among several types from the list above) can be coupled at or within the ion source 10 to produce the desired type of ions. In this case, the control unit must be configured to select beforehand, by means of the extractor filter, the nature of the ions to be used according to the instructions included in the scanning pattern.

FIG. 7 presents the simplified structure of a control unit 70 implementing the processing method according to the invention (for example the particular embodiment described above in relation to FIGS. 1 and 2). This device comprises a random-access memory 73 (for example a RAM memory), a processing unit 71, equipped for example with a processor, and controlled by a computer program stored in a read only memory 72 (for example a ROM memory or a hard disc). On initialization, the code instructions of the computer program are for example loaded into the RAM 73 before being executed by the processor of the processing unit 71. The processing unit 71 receives as input a scan pattern 70E. The processor of the processing unit 71 processes the scan pattern 70E and generates driving commands at output (represented by the arrows 70S) according to the instructions of the program stored in the memory 72. The processing unit 71 thus delivers at the output, the control commands necessary for controlling the scanning means (as described previously, in any one of its various embodiments) of the internal surface of the accelerating cavity or cavities to be treated.

It should be noted that this FIG. 7 illustrates only one particular way, among several possible, of carrying out the algorithm detailed above, in relation to FIG. 1. Indeed, the technique of the invention is carried out indifferently:

on a reprogrammable calculation machine (a PC computer, a DSP processor or a microcontroller) executing a program comprising a sequence of instructions; or

on a dedicated calculation machine (for example a set of logic gates such as an FPGA or an ASIC, or any other hardware module).

In the case where the invention is implemented on a reprogrammable calculating machine, the corresponding program (that is to say the sequence of instructions) can be stored in a removable storage medium (such as for example a diskette, a CD-ROM or a DVD-ROM) or not, this storage medium being partially or totally readable by a computer or a processor.

1. A method for treating a surface of at least one elementary particle accelerating cavity of an accelerator module, wherein the method is implemented by a device and comprises:
scanning an inner surface of said at least one cavity, by displacement of a particle beam respect to said inner surface or vice-versa.

2. The method according to claim 1, wherein said scanning is preceded by:
introducing into said at least one cavity, via an orifice of the accelerator module, of an electric and/or magnetic scanning head of the inner surface;
vacuum of generating the particle beam towards the scanning head introduced into said at least one cavity;
said scanning being implemented by activating the scanning head.

3. The method according to claim 2, wherein the scanning comprises rotating said at least one cavity with respect to said scanning head or vice-versa.

4. The method claim 2, wherein the scanning comprises gliding the scanning head with respect to said at least cavity or vice-versa.

5. The method according to claim 1, wherein, the inner surface of said at least one cavity being made of niobium, the particle beam generating comprises selecting a beam of nitrogen ions having single or multiple electric charge.

6. A non-transitory computer readable medium comprising program code instructions stored thereon to execute a treatment method, when executed on a computer of a device, wherein the treatment method comprises:
the device treating a surface of at least one elementary particle accelerating cavity of an accelerator module by scanning an inner surface of said at least one cavity, by displacement of a particle beam respect to said inner surface or vice-versa.

7. (canceled)

8. A device for treating a surface of at least one elementary particle accelerating cavity, wherein the device comprises:
a source of a particle beam; and
means for scanning an inner surface of said at least one cavity by moving the particle beam respect to respect to said inner surface or vice-versa.

9. The device according to claim 8, comprising:
means for introducing into said at least one cavity, an electric and/or magnetic scanning head of the inner surface, wherein the means for introducing and the scanning head are configured to be insertable into said at least one cavity; and
wherein the source of the particle beam comprises means for generating in vacuum the particle beam in a direction towards the scanning head.

10. The device according to claim 9, comprising the scanning head, wherein the scanning head comprises a beam deflector able to deviate the beam generated towards the inner surface and a beam exit aperture arranged respect to the beam deflector so as to let the deviated beam travel towards the inner surface.

11. The device according to claim 9, wherein the means for scanning comprises means for rotating said at least one cavity with respect to the scanning head or vice-versa.

12. The device according to claim 9, wherein the means for scanning comprises means for gliding said at least one cavity respect to the scanning head or vice-versa.

13. The device according to claim 12, wherein the accelerator module comprises a plurality of successive accelerating cavities, and the means for gliding are configured to introduce successively the scanning head to operate a scan of the inner surface of each of said cavities of said plurality.

14. The device according to claim 9, wherein the accelerator module comprises a plurality of successive accelerating cavities, and the means for introducing comprises a plurality of scanning heads disposed successively along the means for introducing, each scanning head being configured to perform a scanning of the inner surface of a different cavity of said plurality of successive accelerating cavities.

15. The device according to claim 14, comprising:
said at least one cavity, which has first and second flanges;
a connection and vacuum guide connecting said means for generating in vacuum to the first flange; and
an absorbent closure member coupled to the second flange;
and wherein said at least one cavity, said connection and vacuum guide, said means for generating in vacuum and said absorbent closure member form a treatment chamber of said at least one cavity able to be pumped down to vacuum.

16. (canceled)
